(19) United States
(12) Patent Application Publication
(10) Pub. No.: US 2023/0112883 A1
(43) Pub. Date: Apr. 13, 2023

(54) TWO-DIMENSIONAL MATERIAL STRUCTURE, SEMICONDUCTOR DEVICE INCLUDING THE TWO-DIMENSIONAL MATERIAL STRUCTURE, AND METHOD OF MANUFACTURING THE SEMICONDUCTOR DEVICE

(71) Applicant: Samsung Electronics Co., Ltd., Suwon-si (KR)

(72) Inventors: Minsu SEOL, Seoul (KR); Keunwook SHIN, Yongin-si (KR); Junyoung KWON, Seoul (KR); Minseok YOO, Suwon-si (KR); Changseok LEE, Gwacheon-si (KR)

(73) Assignee: Samsung Electronics Co., Ltd., Suwon-si (KR)

(21) Appl. No.: 17/690,376

(22) Filed: Mar. 9, 2022

(30) Foreign Application Priority Data
Oct. 8, 2021 (KR) 10-2021-0134444

(51) Int. Cl. H01L 29/76; H01L 29/16; H01L 29/24; H01L 29/786; H01L 21/02; H01L 29/66

(52) U.S. Cl. CPC H01L 29/7606; H01L 29/1606; H01L 29/24; H01L 29/78618; H01L 29/78696; H01L 21/02521; H01L 21/02527; H01L 21/02568; H01L 21/02178; H01L 21/02181; H01L 21/02189; H01L 21/0228; H01L 21/02164; H01L 21/0217; H01L 21/02274; H01L 29/66969

(57) ABSTRACT

Provided are a two-dimensional material structure, a semiconductor device including the two-dimensional material structure, and a method of manufacturing the semiconductor device. The two-dimensional material structure may include a first insulator including a first dielectric material; a second insulator on the first insulator and including a second dielectric material; a first two-dimensional material film on an exposed surface of the first insulator; and a second two-dimensional material film provided on an exposed surface of the second insulator. The first and second two-dimensional material films may include a two-dimensional material having a two-dimensional layered structure, and the second two-dimensional material film may include more layers of the two-dimensional material than the first two-dimensional material film.

### CROSS-REFERENCE TO RELATED APPLICATION

This application is based on and claims priority under 35 U.S.C. § 119 to Korean Patent Application No. 10-2021-0134444, filed on Oct. 8, 2021, in the Korean Intellectual Property Office, the disclosure of which is incorporated by reference herein in its entirety.

### BACKGROUND

### 1. Field

The present disclosure relates to a two-dimensional material structure, a semiconductor device including the two-dimensional material structure, and a method of manufacturing the semiconductor device.

### 2. Description of the Related Art

Small semiconductor devices have been developed to improve the degree of integration of semiconductor devices, and to this end, research into the use of two-dimensional materials in semiconductor devices has been recently conducted. Two-dimensional materials have stable and good characteristics even when having nanoscale thicknesses and are thus considered to be the next generation of materials for limiting and/or preventing a decrease in the performance of small semiconductor devices.

### SUMMARY

Provided are two-dimensional material structures, semiconductor devices including the two-dimensional material structures, and methods of manufacturing the semiconductor devices.

Additional aspects will be set forth in part in the description which follows and, in part, will be apparent from the description, or may be learned by practice of the presented embodiments of the disclosure.

According to an embodiment, a two-dimensional material structure may include a first insulator including a first dielectric material; a second insulator on the first insulator and including a second dielectric material; a first two-dimensional material film on an exposed surface of the first insulator; and a second two-dimensional material film on an exposed surface of the second insulator. The first two-dimensional material film and the second two-dimensional material film each may include a two-dimensional material having a two-dimensional layered structure. The second two-dimensional material film may include more layers of the two-dimensional material than the first two-dimensional material film.

In some embodiments, the first two-dimensional material film and the second two-dimensional material film may be connected to each other.

In some embodiments, the first insulator may include a dielectric substrate including the first dielectric material, and the second insulator may include a dielectric layer on the first insulator.

In some embodiments, the first dielectric material and the second dielectric material may include different materials or materials formed by different methods.

In some embodiments, the first dielectric material may include SiO₂ formed by dry thermal oxidation or Si₃N₄ formed by low-pressure chemical vapor deposition (CVD).

In some embodiments, the second dielectric material may include Al₂O₃, HfO₂, ZrO₂, or SiO₂ formed by atomic layer deposition (ALD).

In some embodiments, the second dielectric material may include SiO₂ or Si₃N₄ formed by plasma enhanced chemical vapor deposition (PECVD).

In some embodiments, the two-dimensional material may include a transition metal dichalcogenide (TMD), graphene, or black phosphorus.

In some embodiments, each of the first two-dimensional material film and the second two-dimensional material film may include about ten or fewer layers.

According to an embodiment, a semiconductor device may include a dielectric substrate including a first dielectric material; a first dielectric layer and a second dielectric layer spaced apart from each other on the dielectric substrate and the second dielectric layer including a second dielectric material; a first two-dimensional material film on a surface of the dielectric substrate between the first dielectric layer and the second dielectric layer; second two-dimensional material films respectively on a surface of the first dielectric layer and a surface of the second dielectric layer; a first electrode and a second electrode on the second two-dimensional material films; and a third electrode between the first electrode and the second electrode. The first two-dimensional material film and the second two-dimensional material film may include a two-dimensional material having a two-dimensional layered structure, and the second two-dimensional material films may include more layers of the two-dimensional material than the first two-dimensional material film.

In some embodiments, the first two-dimensional material film and the second two-dimensional material films may be connected to each other.

In some embodiments, the first two-dimensional material film may form a channel region.

In some embodiments, the first dielectric material and the second dielectric material may include different materials or materials formed by different methods.

In some embodiments, the two-dimensional material may include a transition metal dichalcogenide (TMD), graphene, or black phosphorus.

According to an embodiment, a semiconductor device may include a dielectric substrate including a first dielectric material; a dielectric layer on the dielectric substrate and including a second dielectric material; a two-dimensional material film on the dielectric layer and including a two-dimensional material having a two-dimensional layered structure; a first electrode and a second electrode spaced apart from each other on the two-dimensional material film; and a third electrode between the first electrode and the second electrode.

In some embodiments, the two-dimensional material film may include a single layer of the two-dimensional material.

In some embodiments, the first dielectric material and the second dielectric materials may include different materials or materials formed by different methods.

In some embodiments, the two-dimensional material may include a transition metal dichalcogenide (TMD), graphene, or black phosphorus.

According to an embodiment, a method of manufacturing a semiconductor device may include: preparing a dielectric substrate including a first dielectric material; forming a first dielectric layer and a second dielectric layer spaced apart a distance from each other on the dielectric substrate, the first dielectric layer and the second dielectric layer including a second dielectric material; forming a first two-dimensional material film on a surface of the dielectric substrate, and second two-dimensional material films respectively on the first dielectric layer and the second dielectric layer; forming a first electrode and a second electrode on the first dielectric layer and the second dielectric layer; and forming a third electrode between the first electrode and the second electrode. The first two-dimensional material film and the second two-dimensional material films may include a two-dimensional material having a two-dimensional layered structure, and the second two-dimensional material films may include more layers of the two-dimensional material than the first two-dimensional material film.

In some embodiments, the first two-dimensional material film and the second two-dimensional material film may be connected to each other.

In some embodiments, the first dielectric material and the second dielectric material may include different materials or materials formed by different methods.

In some embodiments, the first dielectric material may include SiO₂ formed by dry thermal oxidation or Si₃N₄ formed by low-pressure chemical vapor deposition (CVD).

In some embodiments, the second dielectric material may include Al₂O₃, HfO₂, ZrO₂, or SiO₂ formed by atomic layer deposition (ALD).

In some embodiments, the second dielectric material may include SiO₂ or Si₃N₄ formed by plasma enhanced chemical vapor deposition (PECVD).

In some embodiments, the two-dimensional material may include a transition metal dichalcogenide (TMD), graphene, or black phosphorus.

In some embodiments, each of the first two-dimensional material film and the second two-dimensional material film may include about tens or fewer layers.

According to an embodiment, a method of manufacturing a semiconductor device may include preparing a dielectric substrate including a first dielectric material; forming a dielectric layer on the dielectric substrate, the dielectric layer including a second dielectric material; forming a two-dimensional material film on the dielectric layer, the two-dimensional material film including a two-dimensional material having a two-dimensional layered structure; forming a first electrode and a second electrode spaced apart from each other on the two-dimensional material film at a distance from each other; and forming a third electrode between the first electrode and the second electrode.

According to an example embodiment, a semiconductor device may include a substrate including a first dielectric material; a first electrode and a second electrode spaced apart from each other on the substrate; a dielectric structure on the substrate, the dielectric structure including a second dielectric material; a two-dimensional material film on the dielectric structure and including a two-dimensional material having a two-dimensional layered structure; a third electrode on the two-dimensional material film between the first electrode and the second electrode; and a gate insulating layer extending between the third electrode and the first electrode, the second electrode, and the two-dimensional material film. The dielectric structure may include a dielectric layer between the substrate and both the first electrode and the second electrode, or the dielectric structure may include a first dielectric layer and a second dielectric layer spaced apart from each other with the first dielectric layer between the substrate and the first electrode and the second dielectric layer between the substrate and the second electrode;

In some embodiments, the dielectric structure may include the first dielectric layer and the second dielectric layer. A thickness of the two-dimensional material film on the first dielectric layer may be greater than a thickness of the two-dimensional material film on a portion of the substrate between the first dielectric layer and the second dielectric layer. The first dielectric material and the second dielectric material may include different materials.

In some embodiments, the dielectric structure may include the dielectric layer. The two-dimensional material film may extend between the third electrode and the dielectric layer. The first dielectric material and the second dielectric material may include different materials.

In some embodiments, the first dielectric material may have a lower degree of defects compared to the second dielectric material.

In some embodiments, the two-dimensional material may include a transition metal dichalcogenide (TMD), graphene, or black phosphorus.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a two-dimensional material structure according to an example embodiment;

FIG. 2 illustrates a two-dimensional material structure according to another example embodiment;

FIG. 3A is a transmission electron microscope (TEM) image of a first two-dimensional material film (single-layer MoS₂ film) formed on an exposed surface of a dielectric substrate (SiO₂ substrate) in the two-dimensional material structure shown in FIG. 2;

FIG. 3B is a TEM image of a second two-dimensional material film (multilayer MoS₂ film) formed on a surface of a dielectric layer (Al₂O₃ layer) in the two-dimensional material structure shown in FIG. 2;

FIG. 4 illustrates a semiconductor device according to an example embodiment;

FIG. 5 illustrates results of a contact resistance measurement according to the number of two-dimensional material (MoS₂) layers;

FIG. 6A to 6E are views illustrating a method of manufacturing the semiconductor device shown in FIG. 4;

FIG. 7 illustrates a semiconductor device according to another example embodiment;

FIG. 8A to 8D are views illustrating a method of manufacturing the semiconductor device shown in FIG. 7;

FIG. 9 illustrates a semiconductor device according to another example embodiment;

FIGS. 10A to 100 illustrate memory devices according to some example embodiments; and

FIGS. 11A and 11B illustrate circuit elements according to some example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, example embodiments will be described with reference to the accompanying drawings. In the drawings, like reference numerals refer to like elements, and the sizes of elements may be exaggerated for clarity of illustration. The embodiments described herein are for illustrative purposes only, and various modifications may be made therein.

In the following description, when an element is referred to as being “above” or “on” another element, it may be directly on an upper, lower, left, or right side of the other element while making contact with the other element or may be above an upper, lower, left, or right side of the other element without making contact with the other element. The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary, and are not limited to the stated order thereof.

In the present disclosure, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples or example terms are just used herein to describe technical ideas and should not be considered for purposes of limitation unless defined by the claims.

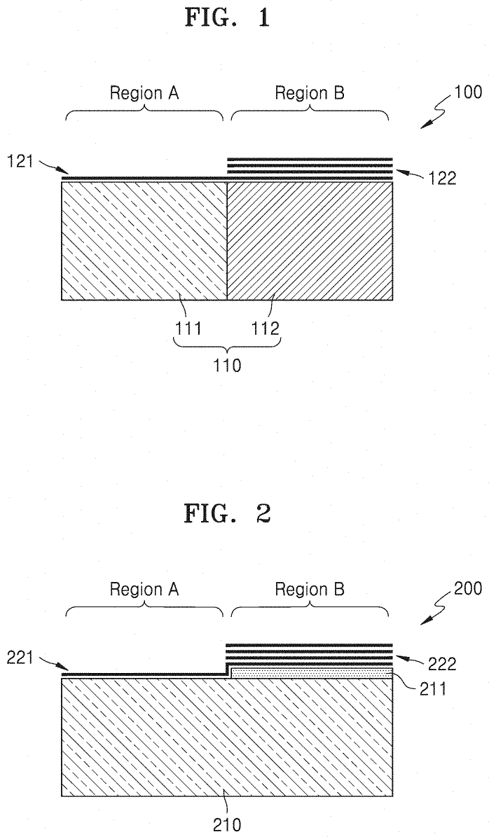

FIG. 1 illustrates a two-dimensional material structure 100 according to an example embodiment.

Referring to FIG. 1, a substrate 110 including a first insulator 111 and a second insulator 112 is provided. The first insulator 111 is provided in Region A of the substrate 110, and the second insulator 112 is provided in Region B of the substrate 110.

The first insulator 111 may include a first dielectric material, and the second insulator 112 may include a second dielectric material. Here, the first and second dielectric materials may have different degrees of defects. For example, the first dielectric material may have a lower degree of defects than the second dielectric material. The first and second dielectric materials may include different dielectric materials and/or dielectric materials formed by different methods.

The first dielectric material may have a lower degree of defects than the second dielectric material because the first dielectric material is formed through a high-temperature process. The first dielectric material may include, for example, SiO₂ formed by dry thermal oxidation, or Si₃N₄ formed by low-pressure chemical vapor deposition (CVD). However, embodiments are not limited thereto.

The second dielectric material may include, for example, Al₂O₃, HfO₂, ZrO₂, or SiO₂ formed by atomic layer deposition (ALD). The second dielectric material may include, for example, SiO₂ or Si₃N₄ formed by plasma enhanced CVD (PECVD). However, embodiments are not limited thereto. In an example, the first dielectric material may include SiO₂ formed by dry thermal oxidation, and the second dielectric material may include Al₂O₃ formed by ALD.

A first two-dimensional material film 121 is provided on an exposed upper surface of the first insulator 111, and a second two-dimensional material film 122 is provided on an exposed upper surface of the second insulator 112. Here, the first and second two-dimensional material films 121 and 122 may each include a two-dimensional material having a two-dimensional layered structure.

The two-dimensional material, which has a crystal structure in which atoms are two-dimensionally bonded together, exhibits good electrical characteristics, and even when having a small thickness in nanoscale, the two-dimensional material may maintain high mobility without significant variations in the characteristics thereof. The two-dimensional material may have a single-layer structure or a multilayer structure. Each layer of the two-dimensional material may have an atomic-level thickness.

The two-dimensional material may include a transition metal dichalcogenide (TMD), graphene, or black phosphorus (BP). However, the listed materials are merely examples, and the two-dimensional material may include other various materials.

The TMD is a two-dimensional material having semiconductor properties, and is a compound of a transition metal and a chalcogen element. Here, the transition metal may include, for example, at least one selected from the group consisting of Mo, W, Nb, V, Ta, Ti, Zr, Hf, Co, Tc, and Re, and the chalcogen element may include, for example, at least one selected from the group consisting of S, Se, and Te. For example, the TMD may include MoS₂, MoSe₂, MoTe₂, WS₂, WSe₂, WTe₂, ZrS₂, ZrSe₂, HfS₂, HfSe₂, NbSe₂, ReSe₂, or the like. However, embodiments are not limited thereto.

Graphene refers to a material having a hexagonal honeycomb structure in which carbon atoms are two-dimensionally bonded together. BP is a semiconductor material having a structure in which phosphorus (P) atoms are two-dimensionally bonded together.

Each of the first and second two-dimensional material films 121 and 122 may have about ten or fewer layers. However, embodiments are not limited thereto. Here, the second two-dimensional material film 122 may include more layers of the two-dimensional material than the first two-dimensional material film 121. For example, the first two-dimensional material film 121 may have a single layer, and the second two-dimensional material film 122 may have two or more layers. For example, the first two-dimensional material film 121 may have two or more layers, and the second two-dimensional material film 122 may have more layers, for example, three or more layers, than the first two-dimensional material film 121. The first and second two-dimensional material films 121 and 122 may be connected to each other.

The first and second two-dimensional material films 121 and 122 have different numbers of layers of the two-dimensional material because of the first and second insulators 111 and 112 provided thereunder. As described above, the first dielectric material of the first insulator 111 may have a lower degree of defects than the second dielectric material of the second insulator 112. In this case, when the two-dimensional material is grown on the upper surfaces of the first and second insulators 111 and 112 by, for example, CVD, the first and second two-dimensional material films 121 and 122 having different numbers of layers of the two-dimensional material may be formed because of different growth rates of the two-dimensional material on the upper surfaces of the first and second insulators 111 and 112.

The growth rate of the two-dimensional material is higher on the second dielectric material having a relatively high degree of defects than on the first dielectric material having a relatively low degree of defects. Therefore, the two-dimensional material may grow faster on the upper surface of the second insulator 112 than on the upper surface of the first insulator 111. After the growth of the two-dimensional material is completed, the second two-dimensional material film 122 formed on the upper surface of the second insulator 112 may have more layers of the two-dimensional material than the first two-dimensional material film 121 formed on the upper surface of the first insulator 111.

In the present embodiment, the first and second insulators 111 and 112 of the two-dimensional material structure 100 may function such that the first two-dimensional material film 121 having a relatively small number of layers (for example, a single layer) may be selectively formed on the first insulator 111, and the second two-dimensional material film 122 having more layers than the first two-dimensional material film 121 may be selectively formed on the second insulator 112.

FIG. 2 illustrates a two-dimensional material structure 200 according to another example embodiment. In the following description, differences from the above-described embodiment will be mainly described.

Referring to FIG. 2, a dielectric layer 211 is provided on a dielectric substrate 210. The dielectric layer 211 partially covers the upper surface of the dielectric substrate 210. The upper surface of the dielectric substrate 210 is exposed in Region A of the dielectric substrate 210, and the dielectric layer 211 is provided in Region B of the dielectric substrate 210.

The dielectric substrate 210 may include a first dielectric material, and the dielectric layer 211 may include a second dielectric material. The first dielectric material may have a lower degree of defects than the second dielectric material. The first and second dielectric materials may include different dielectric materials and/or dielectric materials formed by different methods.

The first dielectric material may include, for example, SiO₂ formed by dry thermal oxidation, or Si₃N₄ formed by low-pressure CVD. The second dielectric material may include, for example, Al₂O₃, HfO₂, ZrO₂, or SiO₂ formed by ALD; or SiO₂ or Si₃N₄ formed by PECVD. However, the listed materials are merely examples.

A first two-dimensional material film 221 is provided on an exposed portion of the upper surface of the dielectric substrate 210, and a second two-dimensional material film 222 is provided on the upper surface of the dielectric layer 211. Here, the first and second two-dimensional material films 221 and 222 may each include a two-dimensional material having a two-dimensional layered structure. The two-dimensional material may include, for example, a TMD, graphene, or BP.

Each of the first and second two-dimensional material films 221 and 222 may have about ten or fewer layers, but are not limited thereto. The second two-dimensional material film 222 may include more layers of the two-dimensional material than the first two-dimensional material film 221. As described above, the two-dimensional material grows at a higher rate on the dielectric layer 211, which includes the second dielectric material, than the dielectric substrate 210, which includes the first dielectric material. The first and second two-dimensional material films 221 and 222 may be connected to each other.

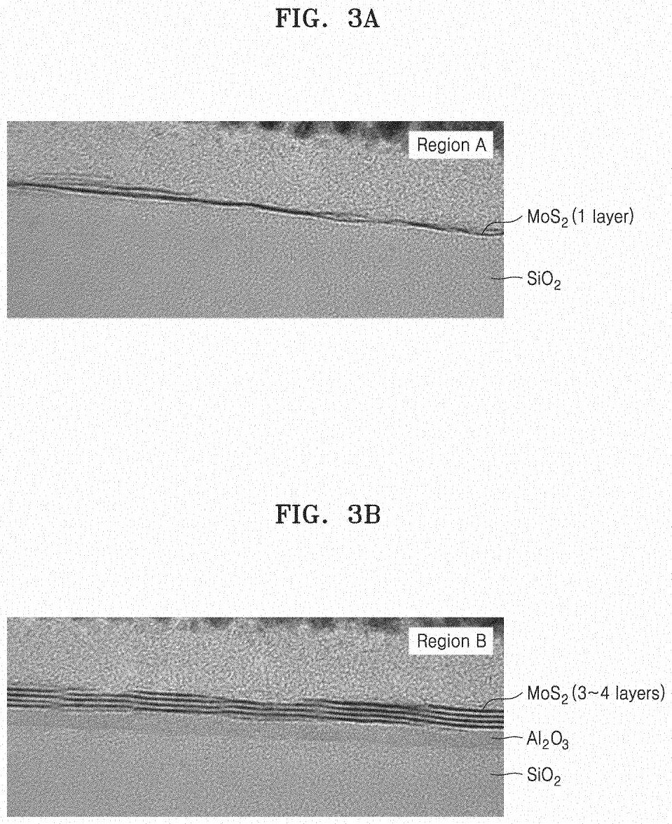

FIGS. 3A and 3B show a transmission electron microscope (TEM) of the first two-dimensional material film 221 formed in Region A of the two-dimensional material structure 200 shown in FIG. 2 and a TEM image of the second two-dimensional material film 222 formed in Region B of the two-dimensional material structure 200 shown in FIG. 2. Here, an SiO₂ substrate formed by dry thermal oxidation was used as the dielectric substrate 210, and an Al₂O₃ layer formed by ALD was used as the dielectric layer 211. Then, MoS₂ was grown on the surfaces of the SiO₂ substrate and the Al₂O₃ layer by CVD to form the first and second two-dimensional material films 221 and 222.

FIG. 3A shows a MoS₂ film (the first two-dimensional material film 221) formed on an exposed surface of the SiO₂ substrate. FIG. 3B shows a MoS₂ film (the second two-dimensional material film 222) formed on a surface of the Al₂O₃ layer. Referring to FIGS. 3A and 3B, it may be seen that the MoS₂ film formed on the exposed surface of the SiO₂ substrate has a single layer, and the MoS₂ film formed on the surface of the Al₂O₃ layer has a plurality of layers (about three to four layers).

Hereinafter, a semiconductor device employing the two-dimensional material structure 200 will be described. The semiconductor device may be, for example, a field effect transistor (FET).

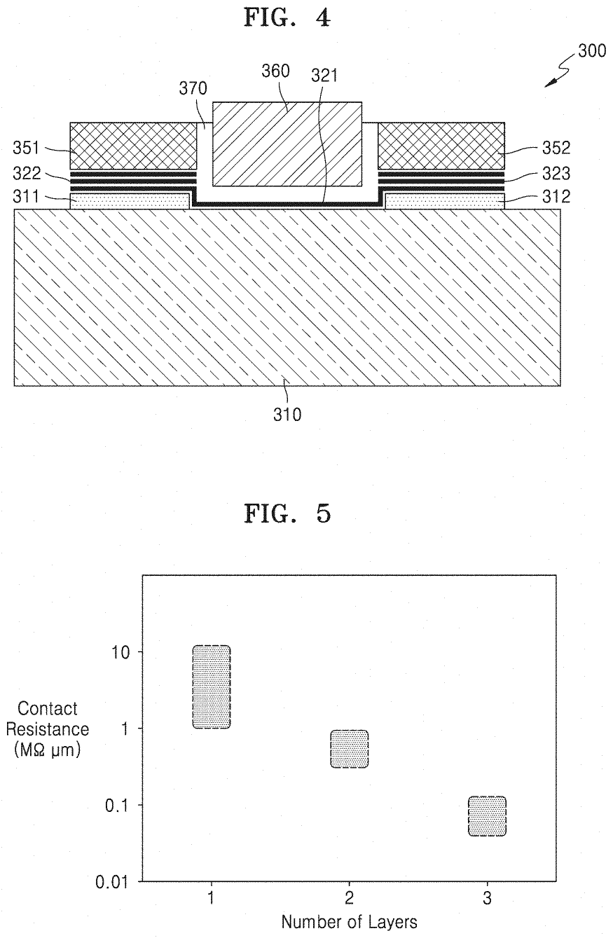

FIG. 4 illustrates a semiconductor device 300 according to an example embodiment.

Referring to FIG. 4, first and second dielectric layers 311 and 312 are provided on a dielectric substrate 310 at a distance from each other. The dielectric substrate 310 may include a first dielectric material, and the first and second dielectric layers 311 and 312 may include a second dielectric material. The first dielectric material may have a lower degree of defects than the second dielectric material. The first and second dielectric materials may include different dielectric materials and/or dielectric materials formed by different methods.

The first dielectric material of the dielectric substrate 310 may include, for example, SiO₂ formed by dry thermal oxidation or Si₃N₄ formed by low-pressure CVD. The second dielectric material of the first and second dielectric layers 311 and 312 may include, for example, Al₂O₃, HfO₂, ZrO₂, or SiO₂ formed by ALD, or SiO₂ or Si₃N₄ formed by PECVD. However, the listed materials are merely examples.

A first two-dimensional material film 321 is provided on the upper surface of the dielectric substrate 310 between the first and second dielectric layers 311 and 312, that is, on an exposed upper surface of the dielectric substrate 310. In addition, second two-dimensional material films 322 and 323 are provided on the upper surfaces of the first and second dielectric layers 311 and 312, respectively. The first and second two-dimensional material films 321, 322, and 323 may each include a two-dimensional material having a two-dimensional layered structure. The two-dimensional material may include, for example, a TMD, graphene, or BP. Each of the first and second two-dimensional material films 321, 322, and 323 may have about ten or fewer layers, but is not limited thereto.

The first two-dimensional material film 321 may include fewer layers of the two-dimensional material than the second two-dimensional material films 322 and 323. The first two-dimensional material film 321 may form a channel region of a transistor. For example, the first two-dimensional material film 321 may include a single-layered two-dimensional material. However, embodiments are not limited thereto.

The second two-dimensional material films 322 and 323 may include more layers of the two-dimensional material than the first two-dimensional material film 321. For example, when the first two-dimensional material film 321 has a single layer, each of the second two-dimensional material films 322 and 323 may have two or more layers. As described above, the reason for this is that the two-dimensional material grows at a higher rate on the first and second dielectric layers 311 and 312, which include the second dielectric material, than on the dielectric substrate 310, which includes the first dielectric material. The first and second two-dimensional material films 321, 322, and 323 may be connected to each other.

A source electrode 351 may be provided on the upper surface of the second two-dimensional material film 322 provided on the first dielectric layer 311, and a drain electrode 352 may be provided on the upper surface of the second two-dimensional material film 323 provided on the second dielectric layer 312. A gate insulating layer 370 may be provided on the first two-dimensional material film 321 between the source electrode 351 and the drain electrode 352. The gate insulating layer 370 may include, for example, SiO₂ or Si₃N₄, but this is merely an example.

A gate electrode 360 is provided on the gate insulating layer 370 between the source electrode 351 and the drain electrode 352. The gate electrode 360 may include, for example, a conductive metal such as gold, silver, or aluminum; a conductive metal oxide; or a conductive metal nitride.

In the present embodiment, the first two-dimensional material film 321 including the two-dimensional material is formed as a channel region between the first and second dielectric layers 311 and 312. A channel region formed of silicon may result in a decrease in mobility and an increase in threshold voltage dispersion as the thickness of the channel region decreases, and may also result in a significant decrease in performance because of a short channel effect as the length of the channel region decreases, thereby limiting scale down. However, a channel region formed of a two-dimensional material may have high performance even when the channel region has a nanoscale thickness, and may decrease limitations on scale down because a short channel effect occurs less in the channel region formed of a two-dimensional material than a channel region formed of silicon.

In the present embodiment, the first two-dimensional material film 321 formed between the first and second dielectric layers 311 and 312 may have fewer layers of the two-dimensional material than the second two-dimensional material films 322 and 323 formed on the first and second dielectric layers 311 and 312. Therefore, the first two-dimensional material film 321 forming the channel region may be thinner than the second two-dimensional material films 322 and 323 on which the source electrode 351 and the drain electrode 352 are formed. For example, the first two-dimensional material film 321 forming the channel region may include a single-layered two-dimensional material, and the second two-dimensional material films 322 and 323 on which the source and drain electrodes 351 and 352 are formed may include a multi-layered two-dimensional material.

An increase in the number of layers of the two-dimensional material forming the channel region may result in negative effects such as a difficulty in effective gating, an increase in current leakage caused by a bandgap decrease, and a threshold voltage shift. In the present embodiment, the channel region is formed using the first two-dimensional material film 321 which includes a two-dimensional material having a relatively small number of layers (for example, a single layer), and thus an FET having improved performance may be provided.

In the present embodiment, the second two-dimensional material films 322 and 323, on which the source electrode 351 and the drain electrode 352 are formed, may include a multi-layered two-dimensional material thicker than the single-layered two-dimensional material of the first two-dimensional material film 321, such that upper portions of the first two-dimensional material films 322 and 323 may be less damaged when the source electrode 351 and the drain electrode 352 are formed. In addition, because the multi-layered two-dimensional material has greater carrier density and mobility than the single-layered two-dimensional material, the contact resistance between the second two-dimensional material films 322 and 323 and the source and drain electrodes 351 and 352 may be reduced. As described above, the second two-dimensional material films 322 and 323 including a multi-layered two-dimensional material are formed under the source electrode 351 and the drain electrode 352, thereby decreasing contact resistance and making it possible to provide an FED having further improved performance. The semiconductor device 300 of the present embodiment may be applied to, for example, a transistor of a logic circuit, or a selector transistor of a memory device such as a DRAM.

FIG. 5 illustrates results of a contact resistance measurement according to the number of layers of a two-dimensional material (MoS₂). Referring to FIG. 5, it may be seen that contact resistance decreases as the number of layers of the two-dimensional material (MoS₂) increases.

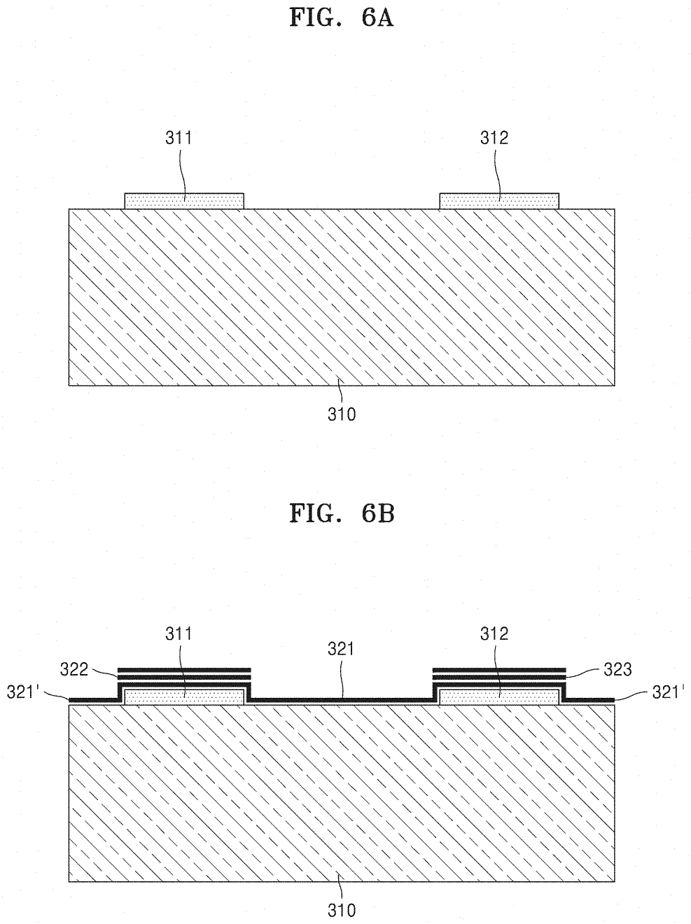

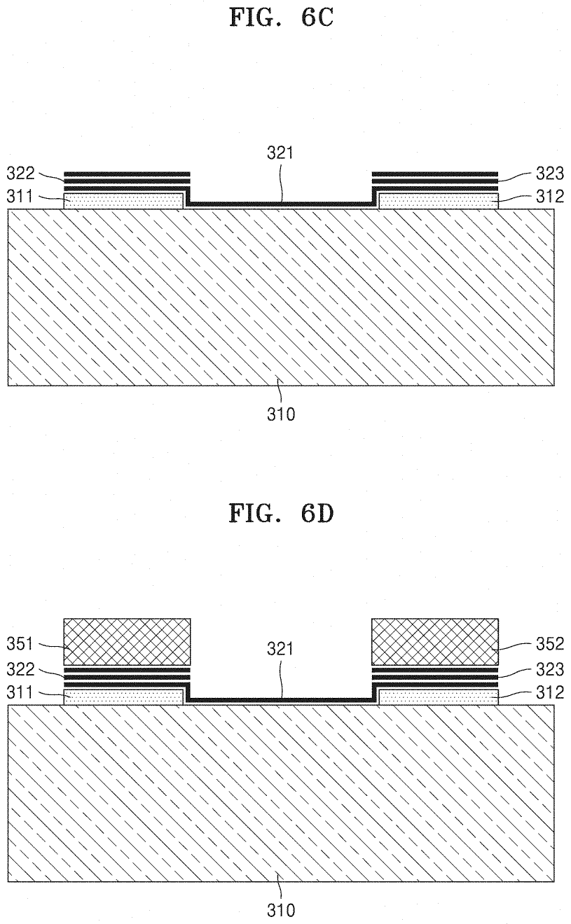

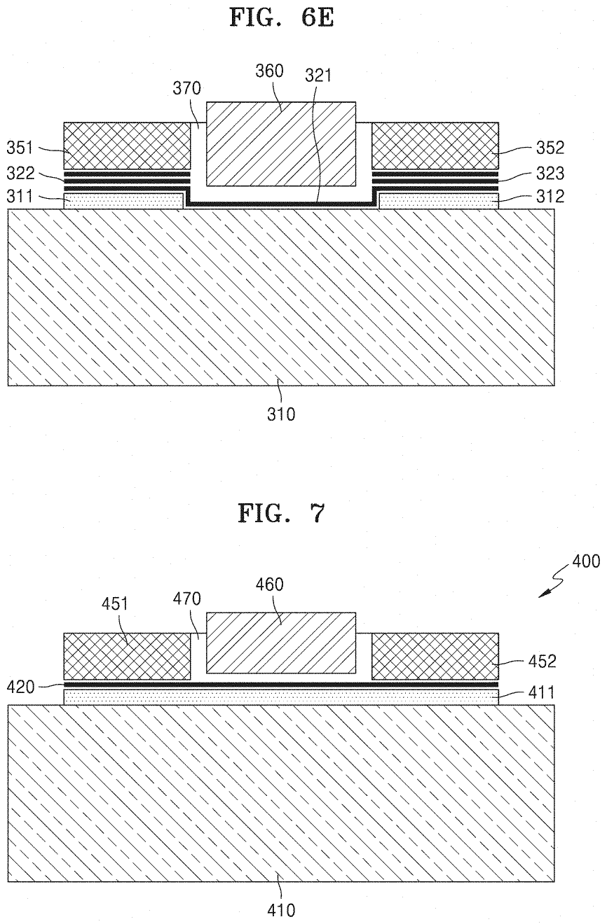

FIGS. 6A to 6E are views illustrating a method of manufacturing the semiconductor device 300 shown in FIG. 4.

Referring to FIG. 6A, first and second dielectric layers 311 and 312 are formed on the upper surface of a dielectric substrate 310 at a distance from each other. The dielectric substrate 310 may include a first dielectric material, and the first and second dielectric layers 311 and 312 may include a second dielectric material. The first and second dielectric layers 311 and 312 may be formed by depositing the second dielectric material on the upper surface of the dielectric substrate 310 and then patterning the second dielectric material.

The first dielectric material may have a lower degree of defects than the second dielectric material. The first and second dielectric materials may include different dielectric materials and/or dielectric materials formed by different methods. The dielectric substrate 310 may include, for example, SiO₂ formed by dry thermal oxidation or Si₃N₄ formed by low-pressure CVD. The first and second dielectric layers 311 and 312 may include, for example, Al₂O₃, HfO₂, ZrO₂, or SiO₂ formed by ALD, or SiO₂ or Si₃N₄ formed by PECVD. However, the listed materials are merely examples.

Referring to FIG. 6B, a first two-dimensional material film 321 (321′) is formed on an exposed upper surface of the dielectric substrate 310, and second two-dimensional material films 322 and 323 are formed on the first and second dielectric layers 311 and 312. The first two-dimensional material film 321 is formed on a portion of the upper surface of the dielectric substrate 310, which is between the first and second dielectric layers 311 and 312, and on a portion of the upper surface of the dielectric substrate 310, which is outside the first and second dielectric layers 311 and 312.

The first and second two-dimensional material films 321, 322, and 323 may each include a two-dimensional material having a two-dimensional layered structure. The two-dimensional material may include, for example, a TMD, graphene, or BP. The TMD is a compound of a transition metal and a chalcogen element. Here, the transition metal may include, for example, at least one selected from the group consisting of Mo, W, Nb, V, Ta, Ti, Zr, Hf, Co, Tc, and Re, and the chalcogen element may include, for example, at least one selected from the group consisting of S, Se, and Te. For example, the TMD may include MoS₂, MoSe₂, MoTe₂, WS₂, WSe₂, WTe₂, ZrS₂, ZrSe₂, HfS₂, HfSe₂, NbSe₂, ReSe₂, or the like. Graphene refers to a material having a hexagonal honeycomb structure in which carbon atoms are two-dimensionally bonded together. In addition, BP is a semiconductor material having a structure in which phosphorus (P) atoms are two-dimensionally bonded together.

The first and second two-dimensional material films 321, 322, and 323 may be formed by CVD such as metal organic CVD (MOCVD), PECVD, or thermal CVD, but are not limited to.

As described above, the first dielectric material of the dielectric substrate 310 has a lower degree of defects than the second dielectric material of the first and second dielectric layers 311 and 312. Therefore, the growth rate of the two-dimensional material may be lower on the upper surface of the dielectric substrate 310 having a relatively low degree of defects than on the upper surfaces of the first and second dielectric layers 311 and 312. Therefore, the second two-dimensional material films 322 and 323 may have more layers of the two-dimensional material than the first two-dimensional material film 321. As a result, the second two-dimensional material films 322 and 323 formed on the first and second dielectric layers 311 and 312 may be thicker than the first two-dimensional material film 321 formed on the dielectric substrate 310. Each of the first and second two-dimensional material films 321, 322, and 323 may have about ten or fewer layers, but is not limited thereto. Thereafter, referring to FIG. 6C, a portion 321′ of the first two-dimensional material film 321, which is formed outside the first and second dielectric layers 311 and 312, may be removed.

Referring to FIG. 6D, a source electrode 351 is formed by depositing a conductive material on the upper surface of the second two-dimensional material film 322 formed on the first dielectric layer 311, and a drain electrode 352 is formed by depositing a conductive material on the upper surface of the second two-dimensional material film 323 formed on the second dielectric layer 312. Next, referring to FIG. 6E, a gate insulating layer 370 is formed on the first two-dimensional material film 321 between the source electrode 351 and the drain electrode 352, and a gate electrode 360 is formed by depositing a conductive material on the gate insulating layer 370.

FIG. 7 illustrates a semiconductor device 400 according to another example embodiment.

Referring to FIG. 7, a dielectric layer 411 is provided on a dielectric substrate 410. Here, a portion of the upper surface of the dielectric substrate 410, which is outside the dielectric layer 411, may be exposed without being covered by the dielectric layer 411.

The dielectric substrate 410 may include a first dielectric material, and the dielectric layer 411 may include a second dielectric material. The first dielectric material may have a lower degree of defects than the second dielectric material. The first and second dielectric materials may include different dielectric materials and/or dielectric materials formed by different methods.

A two-dimensional material film 420 is provided on the upper surface of the dielectric layer 411. The two-dimensional material film 420 may include a two-dimensional material having a two-dimensional layered structure. The two-dimensional material may include, for example, a TMD, graphene, or BP. The two-dimensional material film 420 may have about ten or fewer layers, but is not limited thereto. The two-dimensional material film 420 may include a relatively small number of layers of the two-dimensional material. For example, the two-dimensional material film 420 may include, for example, a single-layered two-dimensional material.

A source electrode 451 and a drain electrode 452 are provided on the upper surface of the two-dimensional material film 420 at a distance from each other. The two-dimensional material film 420 provided between the source electrode 451 and the drain electrode 452 may form a channel region. A gate insulating layer 470 may be provided on the two-dimensional material film 420 between the source electrode 451 and the drain electrode 452, and a gate electrode 460 is provided on the gate insulating layer 470.

In the present embodiment, the two-dimensional material film 420 having a relatively small number of layers (for example, a single layer) and provided between the source electrode 451 and the drain electrode 452 forms the channel region, thereby implementing an FET having improved performance.

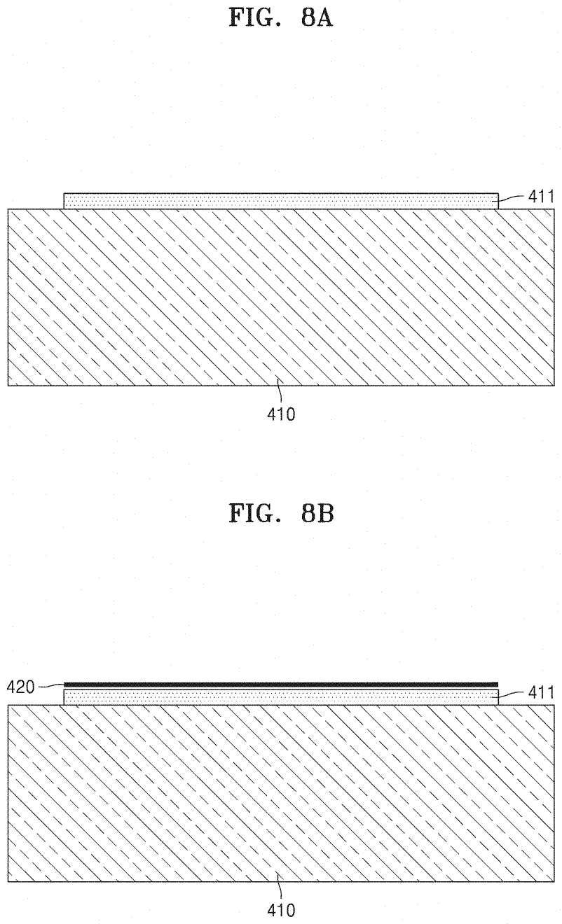

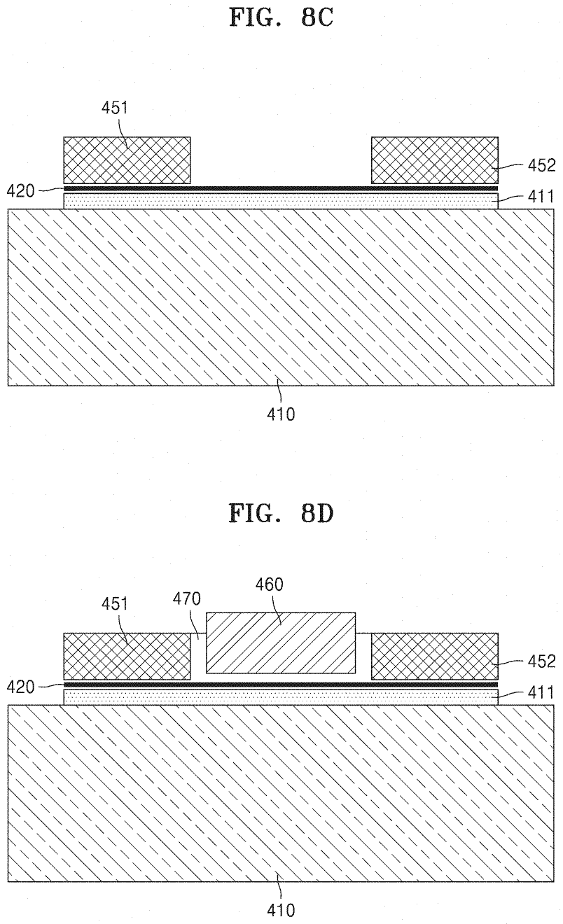

FIGS. 8A to 8D are views illustrating a method of manufacturing the semiconductor device 400 shown in FIG. 7.

Referring to FIG. 8A, a dielectric layer 411 is formed on the upper surface of a dielectric substrate 410. Here, a portion of the upper surface of the dielectric substrate 410, which is outside the dielectric layer 411, may be exposed without being covered by the dielectric layer 411. The dielectric substrate 410 may include a first dielectric material, and the dielectric layer 411 may include a second dielectric material. The dielectric layer 411 may be formed by depositing the second dielectric material on the upper surface of the dielectric substrate 410 and then patterning the second dielectric material.

The first dielectric material may have a lower degree of defects than the second dielectric material. The first and second dielectric materials may include different dielectric materials and/or dielectric materials formed by different methods. The dielectric substrate 410 may include, for example, SiO₂ formed by dry thermal oxidation or Si₃N₄ formed by low-pressure CVD. The dielectric layer 411 may include, for example, Al₂O₃, HfO₂, ZrO₂, or SiO₂ formed by ALD, or SiO₂ or Si₃N₄ formed by PECVD. However, the listed materials are merely examples.

Referring to FIG. 8B, a two-dimensional material film 420 is formed on the upper surface of the dielectric layer 411. The two-dimensional material film 420 may include a two-dimensional material having a two-dimensional layered structure. The two-dimensional material may include, for example, a TMD, graphene, or BP. The two-dimensional material film 420 may be formed, for example, by CVD such as MOCVD, PECVD, or thermal CVD, but is not limited thereto.

The two-dimensional material film 420 may not be formed on the portion of the upper surface of the dielectric substrate 410 which is outside the dielectric layer 411. For example, the two-dimensional material may grow at a higher rate on the dielectric layer 411 having a relatively high degree of defects than on the dielectric substrate 410 having a relatively low degree of defects, and thus the two-dimensional material may be grown only on the dielectric layer 411 by adjusting the growth time of the two-dimensional material to form the two-dimensional material film 420 only on the dielectric layer 411.

Referring to FIG. 8C, a source electrode 451 and a drain electrode 452 are formed by depositing a conductive material on both sides of the two-dimensional material film 420. Next, referring to FIG. 8D, a gate insulating layer 470 is formed on the two-dimensional material film 420 between the source electrode 451 and the drain electrode 452, and a gate electrode 460 is formed by depositing a conductive material on the gate insulating layer 470.

In the present embodiment, the two-dimensional material film 420 may be formed only on the surface of the dielectric layer 411 by controlling the growth time of the two-dimensional material. Therefore, a process of removing the two-dimensional material film 420 from the surface of the dielectric substrate 410 may not be performed, and thus the semiconductor device 400 may be manufactured through simple processes.

FIG. 9 illustrates a semiconductor device according to another example embodiment.

Referring to FIG. 9, the semiconductor device 301 may be similar to the semiconductor device 300 described in FIG. 4, except the semiconductor device includes a dielectric layer 310′ including the first dielectric material on a dielectric substrate 313 including the second dielectric material. Instead of the first and second dielectric layers 311 and 312 in the semiconductor device 300 of FIG. 4, the first and second dielectric layers 311 and 312 are replaced with a dielectric substrate 313 including the second dielectric material.

As described above, according to the one or more of the above example embodiments, in the two-dimensional material structure, a first two-dimensional material film having a single-layered structure and a second two-dimensional material film having a multilayered structure may be selectively formed in desired dielectric regions.

According to the one or more of the above example embodiments, because the channel region of the semiconductor device includes a two-dimensional material, the performance of the semiconductor device may be improved even when the channel region has a small thickness in nanoscale, and limitations on scale down may be overcome. In addition, because the channel region has a small number of two-dimensional material layers (for example, a single layer), situations such as a leakage current increase or a threshold voltage shift may be limited and/or prevented, and an FET having improved performance may be provided. In addition, because the source electrode and the drain electrode are formed on a multi-layered two-dimensional material, contact resistance may be reduced, and thus an FET having further improved performance may be provided. The semiconductor device of the one or more of the example embodiments, may be applied to a transistor of a logic circuit, a selector transistor of a memory device such as a DRAM, or the like. While embodiments have been described, the embodiments are merely examples, and it will be understood by those of ordinary skill in the art that various modifications may be made in the embodiments.

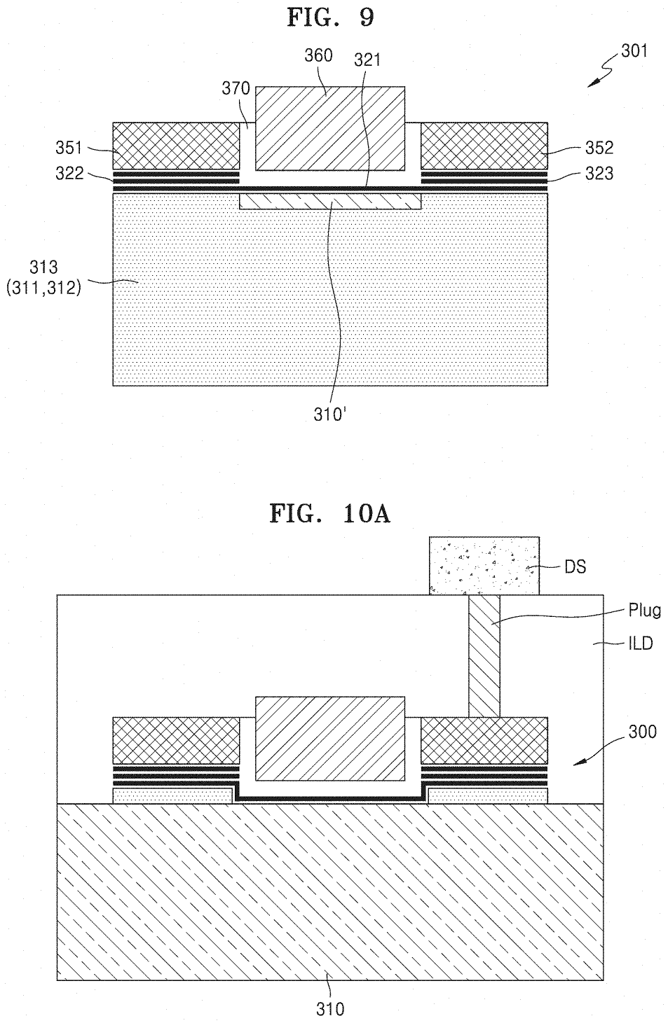

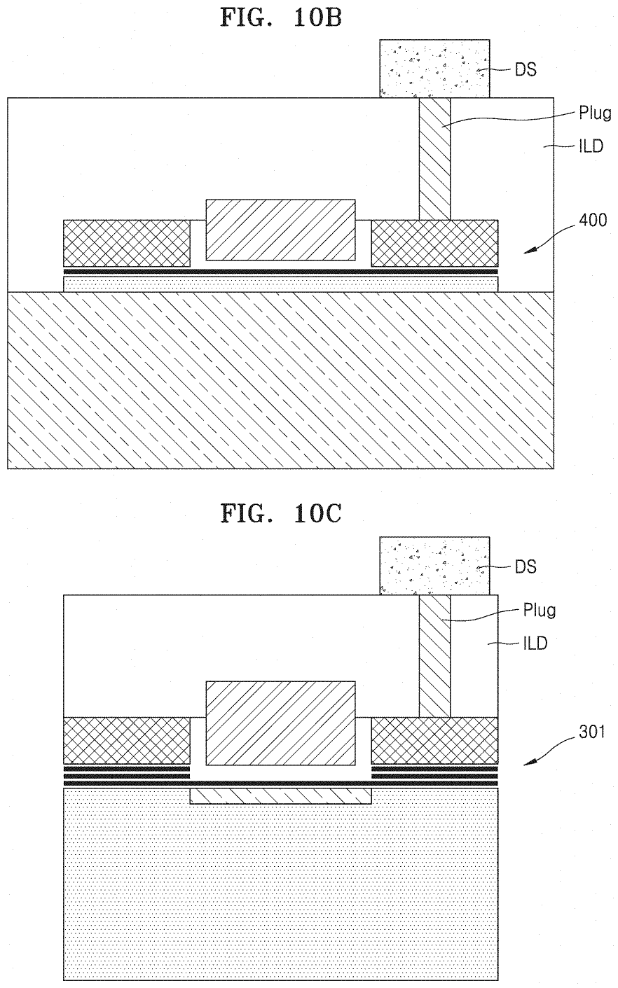

For example, FIGS. 10A to 10C illustrate memory devices according to some example embodiments.

Referring to FIGS. 10A to 100, the semiconductor devices 300, 400, and 301 described in FIGS. 4, 7, and 9 may be covered by an interlayer dielectric ILD layer including an insulating material (e.g., silicon oxide), a data storage DS (e.g., capacitor) on the ILD layer, and conductive plug Plug electrically connected the data storage DS to the drain electrode (see 352 in FIGS. 4 and 9, 452 in FIG. 7). The conductive plug Plug may extend through the ILD layer between the data storage DS and drain electrode.

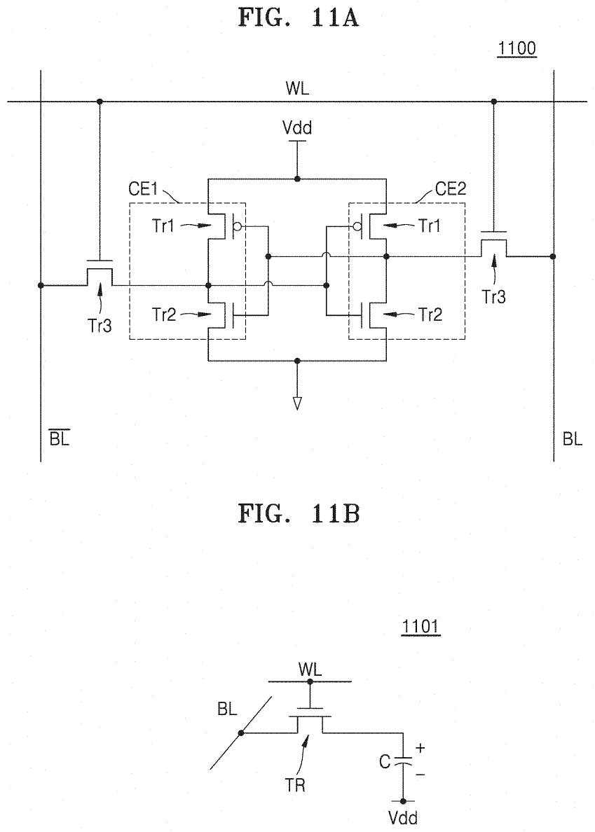

FIGS. 11A and 11B illustrate circuit elements according to some example embodiments.

Referring to FIG. 11A, a circuit element 1100 according to an example embodiment is provided. The circuit element 1100 may be used in a SRAM device.

The circuit element 1110 may include sub-elements CE1 and CE2 that each include a PMOS transistor Tr1 and an NMOS transistor Tr2 disposed between a power terminal Vdd and a ground terminal. The circuit element 1110 may further include a pair of transfer transistors Tr3. A source of the transfer transistor Tr3 is cross-connected to a common node of the PMOS transistor Tr1 and the NMOS transistor Tr2. A power terminal Vdd is connected to the source of the PMOS transistor Tr1, and a ground terminal is connected to the source of the NMOS transistor Tr2. A word line WL may be connected to a gate of the pair of transfer transistors Tr3, and a bit line BL and an inverted bit line/BL may be connected to a drain of each of the pair of transfer transistors Tr3, respectively.

At least one of the transistors Tr1, Tr2, and Tr3 may include one of the semiconductor devices 300, 400, or 301 described above in FIGS. 4, 7, and 9.

Referring to FIG. 11B, a circuit element 1101 according to an example embodiment is provided. The circuit element 1101 may be used in a DRAM device. The circuit element 1101 may include a capacitor C connected to a transistor TR. A word line WL may be connected to a gate of the transistor TR. A bit line BL may be connected one source/drain region of the transistor TR and the capacitor C may be connected to the other source/drain region of the transistor TR. The other end of the capacitor C may be connected to a power supply voltage Vdd. The circuit element 1101 may include any one of the memory devices in FIGS. 10A to 10C using one of the semiconductor device 300, 400, or 301 for the transistor Tr and the data storage DS for the capacitor C.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of inventive concepts as defined by the following claims.

What is claimed is:

1. A two-dimensional material structure comprising:
a first insulator comprising a first dielectric material;
a second insulator provided on the first insulator and comprising a second dielectric material;
a first two-dimensional material film on an exposed surface of the first insulator; and
a second two-dimensional material film on an exposed surface of the second insulator, wherein
the first two-dimensional material film and the second two-dimensional material film each comprise a two-dimensional material having a two-dimensional layered structure, and
the second two-dimensional material film comprises more layers of the two-dimensional material than the first two-dimensional material film.

2. The two-dimensional material structure of claim 1, wherein the first two-dimensional material film and second two-dimensional material film are connected to each other.

3. The two-dimensional material structure of claim 1, wherein
the first insulator comprises a dielectric substrate comprising the first dielectric material, and
the second insulator comprises a dielectric layer on the first insulator.

4. The two-dimensional material structure of claim 1, wherein the first dielectric material and the second dielectric material comprise different materials or materials formed by different methods.

5. The two-dimensional material structure of claim 4, wherein
the first dielectric material comprises SiO₂ formed by dry thermal oxidation or Si₃N₄ formed by low-pressure chemical vapor deposition (CVD).

6. The two-dimensional material structure of claim 4, wherein
the second dielectric material comprises Al₂O₃, HfO₂, ZrO₂, or SiO₂ formed by atomic layer deposition (ALD).

7. The two-dimensional material structure of claim 4, wherein the second dielectric material comprises SiO₂ or Si₃N₄ formed by plasma enhanced chemical vapor deposition (PECVD).

8. The two-dimensional material structure of claim 1, wherein the two-dimensional material comprises a transition metal dichalcogenide (TMD), graphene, or black phosphorus.

9. The two-dimensional material structure of claim 1, wherein each of the first two-dimensional material film and the second two-dimensional material film comprises about ten or fewer layers.

10. A semiconductor device comprising:
a dielectric substrate comprising a first dielectric material;
a first dielectric layer and a second dielectric layer spaced apart from each other on the dielectric substrate, the first dielectric layer and the second dielectric layer comprising a second dielectric material;
a first two-dimensional material film provided on a surface of the dielectric substrate between the first and second dielectric layers;
second two-dimensional material films respectively on a surface of the first dielectric layer and a surface of the second dielectric layer;
a first electrode and a second electrode on the second two-dimensional material films; and
a third electrode between the first electrode and the second electrode,
wherein the first two-dimensional material film and the second two-dimensional material film comprise a two-dimensional material having a two-dimensional layered structure, and
the second two-dimensional material films comprise more layers of the two-dimensional material than the first two-dimensional material film.

11. The semiconductor device of claim 10, wherein the first two-dimensional material film and the second two-dimensional material films are connected to each other.

12. The semiconductor device of claim 10, wherein the first two-dimensional material film forms a channel region.

13. The semiconductor device of claim 10, wherein the first dielectric material and the second dielectric material comprise different materials or materials formed by different methods.

14. The semiconductor device of claim 10, wherein the two-dimensional material comprises a transition metal dichalcogenide (TMD), graphene, or black phosphorus.

15. A semiconductor device comprising:
a dielectric substrate comprising a first dielectric material;
a dielectric layer on the dielectric substrate and comprising a second dielectric material;
a two-dimensional material film on the dielectric layer and comprising a two-dimensional material having a two-dimensional layered structure;
a first electrode and a second electrode spaced apart from each other on the two-dimensional material film; and
a third electrode between the first electrode and the second electrode.

16. The semiconductor device of claim 15, wherein the two-dimensional material film comprises a single layer of the two-dimensional material.

17. The semiconductor device of claim 15, wherein the first dielectric material and the second dielectric material comprise different materials or materials formed by different methods.

18. The semiconductor device of claim 15, wherein the two-dimensional material comprises a transition metal dichalcogenide (TMD), graphene, or black phosphorus.

19. A method of manufacturing a semiconductor device, the method comprising:
preparing a dielectric substrate comprising a first dielectric material;
forming a first dielectric layer and a second dielectric layer spaced apart a distance from each other on the dielectric substrate, the first dielectric layer and the second dielectric layer comprising a second dielectric material;
forming a first two-dimensional material film on a surface of the dielectric substrate, and second two-dimensional material films respectively on the first dielectric layer and second dielectric layer;
forming a first electrode and a second electrode on the first dielectric layer and the second dielectric layer; and
forming a third electrode between the first electrode and the second electrode,
wherein the first two-dimensional material film and the second two-dimensional material film comprise a two-dimensional material having a two-dimensional layered structure, and
the second two-dimensional material films comprise more layers of the two-dimensional material than the first two-dimensional material film.

20. The method of claim 19, wherein the first two-dimensional material film and the second two-dimensional material films are connected to each other.

21. The method of claim 19, wherein the first dielectric material and the second dielectric material comprise different materials or materials formed by different methods.

22. The method of claim 21, wherein the first dielectric material comprises SiO₂ formed by dry thermal oxidation or Si₃N₄ formed by low-pressure chemical vapor deposition (CVD).

23. The method of claim 21, wherein the second dielectric material comprises Al₂O₃, HfO₂, ZrO₂, or SiO₂ formed by atomic layer deposition (ALD).

24. The method of claim 21, wherein the second dielectric material comprises SiO₂ or Si₃N₄ formed by plasma enhanced chemical vapor deposition (PECVD).

25. The method of claim 19, wherein the two-dimensional material comprises a transition metal dichalcogenide (TMD), graphene, or black phosphorus.

26. The method of claim 19, wherein each of the first two-dimensional material film and the second two-dimensional material films comprise about ten or fewer layers.

27. A method of manufacturing a semiconductor device, the method comprising:
preparing a dielectric substrate comprising a first dielectric material;
forming a dielectric layer on the dielectric substrate, the dielectric layer comprising a second dielectric material;
forming a two-dimensional material film on the dielectric layer, the two-dimensional material film comprising a two-dimensional material having a two-dimensional layered structure;
forming a first electrode and a second electrode spaced apart from each other on the two-dimensional material film; and
forming a third electrode between the first electrode and the second electrode.

28. A semiconductor device comprising:
a substrate including a first dielectric material;
a first electrode and a second electrode spaced apart from each other on the substrate;
a dielectric structure on the substrate, the dielectric structure including a second dielectric material, and
the dielectric structure including a dielectric layer between the substrate and both the first electrode and the second electrode, or
the dielectric structure including a first dielectric layer and a second dielectric layer spaced apart from each other with the first dielectric layer between the substrate and the first electrode and the second dielectric layer between the substrate and the second electrode;
a two-dimensional material film on the dielectric structure and comprising a two-dimensional material having a two-dimensional layered structure;
a third electrode on the two-dimensional material film between the first electrode and the second electrode; and
a gate insulating layer extending between the third electrode and the first electrode, the second electrode, and the two-dimensional material film.

29. The semiconductor device of claim 28, wherein
the dielectric structure includes the first dielectric layer and the second dielectric layer,
a thickness of the two-dimensional material film on the first dielectric layer is greater than a thickness of the two-dimensional material film on a portion of the substrate between the first dielectric layer and the second dielectric layer, and
the first dielectric material and the second dielectric material comprise different materials.

30. The semiconductor device of claim 28, wherein
the dielectric structure includes the dielectric layer,
two-dimensional material film extends between the third electrode and the dielectric layer, and
the first dielectric material and the second dielectric material comprise different materials.

31. The semiconductor device of claim 28, wherein
the first dielectric material has a lower degree of defects compared to the second dielectric material.

32. The semiconductor device of claim 28, wherein the two-dimensional material comprises a transition metal dichalcogenide (TMD), graphene, or black phosphorus.
